(19) United States
(12) Patent Application Publication
(10) Pub. No.: US 2023/0335812 A1
(43) Pub. Date: Oct. 19, 2023

(54) BATTERY MODULE

(71) Applicant: AMITA TECHNOLOGIES INC., Taoyuan City (TW)

(72) Inventor: Yuan-Li CHIANG, Taoyuan City (TW)

(21) Appl. No.: 17/746,726

(22) Filed: May 17, 2022

(30) Foreign Application Priority Data
Apr. 15, 2022 (TW) 111114505

(51) Int. Cl. H01M 10/48; G01R 31/3835

(52) U.S. Cl. CPC H01M 10/482; H01M 10/486; G01R 31/3835

(57) ABSTRACT

A battery module includes a body, a plurality of battery units, and a sensing unit. The plurality of battery units is arranged in the body. The sensing unit is arranged in the body and electrically connected with the battery units. The sensing unit is fixed on the battery units, and senses a voltage signal and a temperature signal of each battery unit.

### BACKGROUND

### Technical Field

The present disclosure is related to a battery module, in particular to a battery module with voltage and temperature sensing functions.

### Description of Related Art

In the related art, the lithium-ion batteries (such as lithium-cobalt batteries, lithium-manganese batteries, ternary lithium batteries, lithium-iron batteries, or lithium-titanium-oxide batteries, etc.) are widely used in various electronic products due to their advantages of high energy conversion efficiency, long service life, and high stability. In order to reduce a weight and avoid some problems of abnormal pressure inside the lithium-ion battery during use, most manufacturers use a ductile soft bag as an outer packaging of the lithium-ion battery, that is, a battery pack. In addition, a plurality of battery packs may be connected in series or in parallel according to different power requirements, so as to form a single battery module as the power source of an electronic device.

The safety of batteries is based on monitoring voltage and temperature. In the related art, standard battery modules are used with an external monitoring box to monitor voltage and temperature. However, the configuration with the external monitoring box is inconvenient during use (for example, occupying extra space, accidental loss, etc.), and numerous transmission lines are needed between the battery module and the external monitoring box (for example, the number of transmission lines are depending on the number of battery packs in the battery module). The battery module is prone to have problems (for example, a large resistance value caused by breaking or bending of the transmission lines, etc.) due to bending or collision during transportation or arrangement, and that causes some safety problems of using the battery module.

Therefore, how to design a battery module with integrated sensing function is an important subject studied by the inventor of the present disclosure.

### SUMMARY

One purpose of the present disclosure is to provide a battery module, which integrates a sensing function inside to avoid the battery module connecting a large number of transmission lines externally and occupying extra space. In addition, the sensing function for voltage and temperature is ensured to be normally operated for the battery module, so as to achieve a purpose of improving safety in use of the battery module.

In order to achieve the purpose of the present disclosure, the battery module includes a body, a plurality of battery units, and a sensing unit. The plurality of battery units is arranged in the body. The sensing unit is arranged in the body, and is electrically connected with the plurality of battery units. The sensing unit includes a plurality of solder pads arranged in pairs, and further includes a first-row socket, a second-row socket, and a plurality of temperature sensors. The sensing unit is fixed on the plurality of battery units, and senses the voltage signal and the temperature signal of each battery unit. The plurality of solder pads is soldered with a plurality of electrodes of the battery units. The first-row socket is electrically connected to the plurality of solder pads, and transmits a plurality of voltage signals. The second-row socket transmits a plurality of temperature signals. Each temperature sensor is arranged to straddle an electrical path between one of the pluralities of solder pads and the first-row socket, and senses the temperature signal of each battery unit.

In some embodiments, the battery module further includes an output unit. The output unit is arranged in the body, and is electrically connected to the sensing unit in a pluggable manner. The output unit outputs the plurality of voltage signals and the plurality of temperature signals to outside of the battery module.

In some embodiments, the body includes a groove body and an upper cover. The battery units are accommodated in the groove body. The sensing unit and the output unit are sandwiched between the plurality of battery units and the upper cover.

In some embodiments, the body further includes a frame body sandwiched between the groove body and the upper cover. The frame body is electrically connected to a ground terminal of the sensing unit.

In some embodiments, the output unit includes a first-row pin and a second-row pin arranged perpendicular to each other. The first-row pin is conductively inserted into the first-row socket, and receives the plurality of voltage signals. The second-row pin is conductively inserted into the second-row socket, and receives the plurality of temperature signals.

In some embodiments, the sensing unit further includes a plurality of current limiting elements. Each current limiting element is electrically connected with one of the pluralities of solder pads and the first-row socket respectively.

In some embodiments, the output unit includes a first transmission port and a second transmission port. The first transmission port outputs the plurality of voltage signals to outside of the battery module. The second transmission port outputs the plurality of temperature signals to outside of the battery module.

In summary, the battery module of the present disclosure adopts the architecture of arranging the sensing unit in the body. The external box for monitoring voltage and temperature in the related art, which occupies extra space, is eliminated. The battery module of the present disclosure does not need redundant transmission lines connected between the battery module and the external box. While monitoring the voltage and temperature of each battery unit, a user does not have to worry about accidentally losing the sensing unit during transporting or arranging the battery module, and the problems such as large resistance value, etc., caused by breaking or bending of the transmission lines, may be avoided.

Therefore, the battery module in the present disclosure is ensured for the sensing function of voltage and temperature being normally operated, so as to achieve a purpose of improving safety in use of the battery module.

In order to further understand the techniques, means, and effects of the present disclosure for achieving the intended purpose. Please refer to the following detailed description and drawings of the present disclosure. The drawings are provided for reference and description only, and are not intended to limit the present disclosure.

### BRIEF DESCRIPTION OF DRAWINGS

FIG. 1 is a system architecture diagram of a first embodiment of a battery module of the present disclosure.

FIG. 2 and FIG. 3 are the disassembled schematic diagrams of a second embodiment of the battery module of the present disclosure.

FIG. 4 is a structural diagram of a sensing unit of the battery module of the present disclosure.

FIG. 5 is a cross-sectional view of the battery module of the present disclosure.

### DETAILED DESCRIPTION

The following are specific examples to illustrate some implementations of the present disclosure. A person skilled in the art may understand the advantages and effects of the present disclosure from the content disclosed in this specification. The present disclosure may be implemented or applied through other different specific embodiments, and various details in this specification may also be based on different viewpoints and applications, and various modifications and changes may be made without departing from the concept of the present disclosure.

It should be understood that the structures, the proportions, the sizes, the number of components, and the like in the drawings are only used to cope with the contents disclosed in the specification for understanding and reading by those skilled in the art, and it is not intended to limit the conditions that may be implemented in the present disclosure, and thus is not technically significant. Any modification of the structure, the change of the proportional relationship, or the adjustment of the size, should be within the scope of the technical contents disclosed by the present disclosure without affecting the effects and the achievable effects of the present disclosure.

The technical content and detailed description of the present disclosure will be described below in conjunction with the drawings.

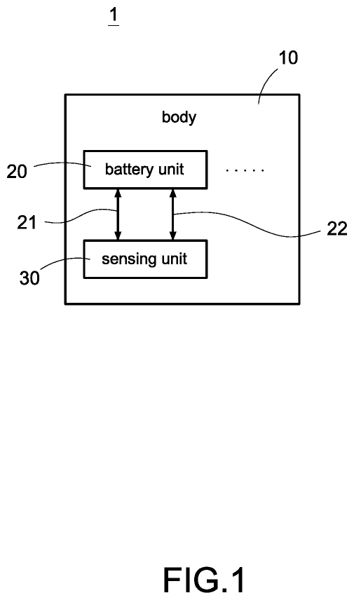

FIG. 1 is a system architecture diagram of a first embodiment of a battery module of the present disclosure.

As shown in FIG. 1, the battery module 1 includes a body 10, a plurality of battery units 20, and a sensing unit 30.

The body 10 is used to accommodate the plurality of battery units 20 and the sensing unit 30. In some embodiments, the body 10 is made of materials with heat resistance, acid resistance, shock resistance, desirable insulation and specific mechanical strength. The material may include rubber, plastic, steel, or aluminum, etc. The rubber may include vulcanized rubber (for example, the sulfur content is above 25% by weight), but there is not limited thereto. The plastic may include high-strength and high-density plastic such as acrylonitrile butadiene styrene (ABS), polypropylene (PP), styrene acrylonitrile resin (also known as AS polyester), polyvinyl chloride (PVC), urea formaldehyde (UF), melamine formaldehyde (MF), etc., but there is not limited thereto.

The plurality of battery units 20 are arranged in the body 10. The battery unit 20 is narrowly defined as a device that converts the stored chemical energy into electrical energy, and may be roughly classified into primary battery, rechargeable battery, and fuel cell. The primary battery is the disposable battery, which is not capable of being recharged and continuously used after the electrical energy is exhausted. The disposable battery may include carbon-zinc battery, alkaline-manganese battery, zinc battery, zinc-air battery, zinc-mercury battery, mercury battery, hydrogen-oxygen battery, magnesium-manganese battery, etc., but there is not limited thereto. The rechargeable battery is the secondary battery or accumulator. The advantage of rechargeable battery is repeatedly usable after recharging. The types of rechargeable battery include lead-acid battery, nickel-cadmium battery (NiCd), nickel-metal hydride battery (NiMH), lithium-ion battery (Li-ion), etc., but there is not limited thereto. The fuel cell is a device that directly converts the chemical energy of fuel into electrical energy through an electrochemical reaction. Unlike the electrochemical cell, the reactants of the fuel cell are not stored in the cell. The fuel cell uses hydrogen to perform oxidization at the anode to oxidize hydrogen into hydrogen ions. Oxygen undergoes a reduction reaction at the cathode to combine with hydrogen ions from the anode to form water. That is, electric current is generated during a redox reaction. The fuel cell may include alkaline fuel cell (AFC), phosphoric acid fuel cell (PAFC), proton exchange membrane fuel cell (PEMFC), molten carbonate fuel cell (MCFC), solid oxide fuel cell (SOFC), and direct methanol fuel cell (DMFC), etc., but there is not limited thereto.

The sensing unit 30 is arranged in the body 10, and is electrically connected with the plurality of battery units 20. In some embodiments, the sensing unit 30 is fixed on the plurality of battery units 20, and configured to sense the voltage signal 21 and the temperature signal 22 of each battery unit 20. In some embodiments, the sensing unit 30 may include a thermocouple (TC), a diode, a thermally sensitive resistance, a resistance temperature detector (RTD), an IC temperature sensor, an acoustic temperature sensor, an infrared sensor, or a microwave sensor, etc., used for sensing the temperature signal 22, but there is not limited thereto.

In some embodiments, the diode may include light-emitting diode (LED), and the light-emitting diode may include red light-emitting diode in a visible light range (for example, aluminum gallium arsenide (AlGaAs), arsenide Gallium phosphide (GaAsP), indium gallium aluminum phosphide (AlGaInP), gallium phosphide doped zinc oxide (GaP:ZnO)), orange light-emitting diode (for example, gallium arsenide phosphide (GaAsP), phosphide Indium gallium aluminum phosphide (AlGaInP), gallium phosphide doped X (GaP:X)), yellow light-emitting diode (for example, gallium arsenide phosphide (GaAsP), indium gallium aluminum phosphide (AlGaInP), gallium phosphide doped nitrogen (GaP:N)), green light-emitting diode (for example, indium gallium nitride (InGaN), gallium nitride (GaN), gallium phosphide (GaP), aluminum indium gallium phosphide (AlGaInP), aluminum gallium phosphide (lGaP), blue light-emitting diode (for example, zinc selenide (ZnSe), indium gallium nitride (InGaN), silicon carbide (SiC)), violet light-emitting diode (for example, indium nitride) gallium (InGaN)), and infrared light-emitting diode (for example, gallium arsenide (GaAs), aluminum gallium arsenide (AlGaAs)) or ultraviolet light-emitting diode (for example, diamond, aluminum nitride (AlN), aluminum gallium nitride (AlGaN), aluminum gallium indium nitride (AlGaInN), etc., and the light-emitting diode may also include organic light-emitting diode (OLED), but there is not limited thereto.

Therefore, the battery module 1 of the present disclosure adopts the architecture of arranging the sensing unit 30 in the body 10. The external box for monitoring voltage and temperature in the related art, which occupies extra space, is eliminated. The battery module 1 of the present disclosure does not need redundant transmission lines connected between the battery module 1 and the external box. While monitoring the voltage and temperature of each battery unit 20, a user does not have to worry about accidentally losing the sensing unit during transporting or arranging the battery module 1, and the problems such as large resistance value, etc, caused by breaking or bending of the transmission lines, may be avoided.

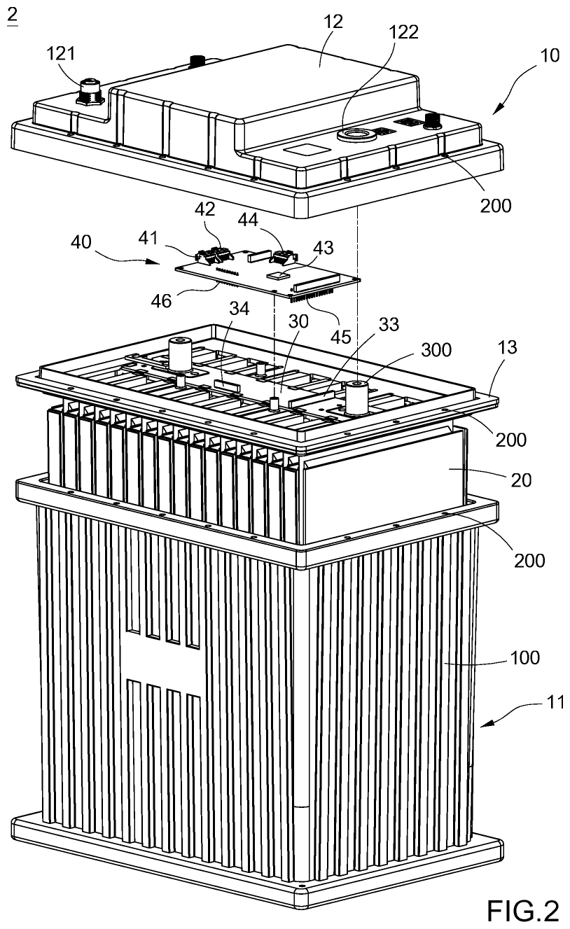

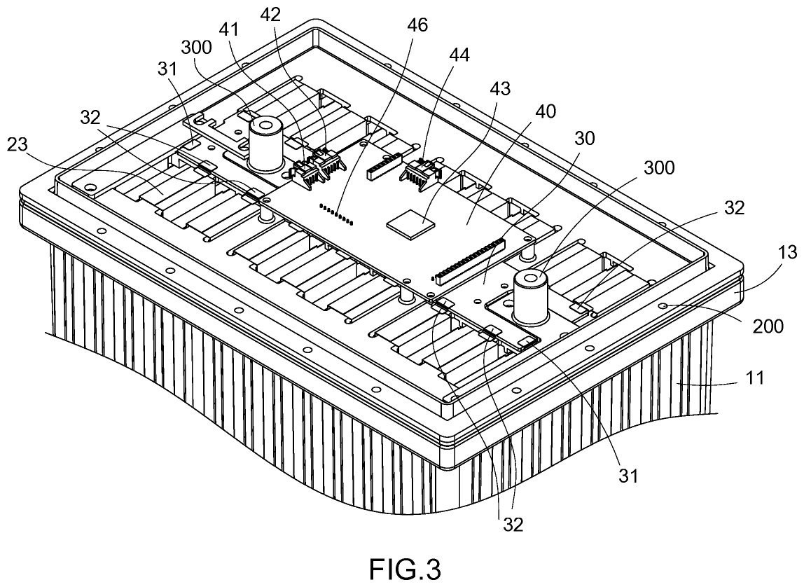

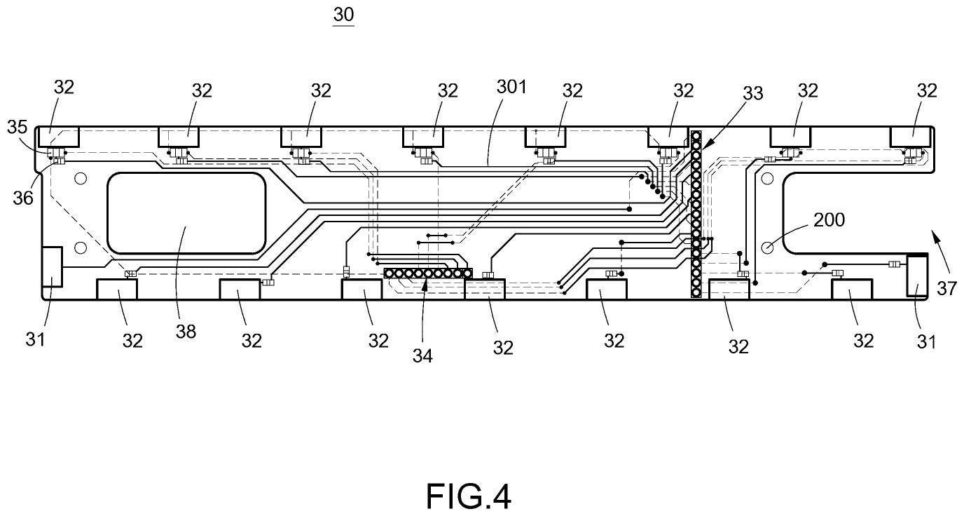

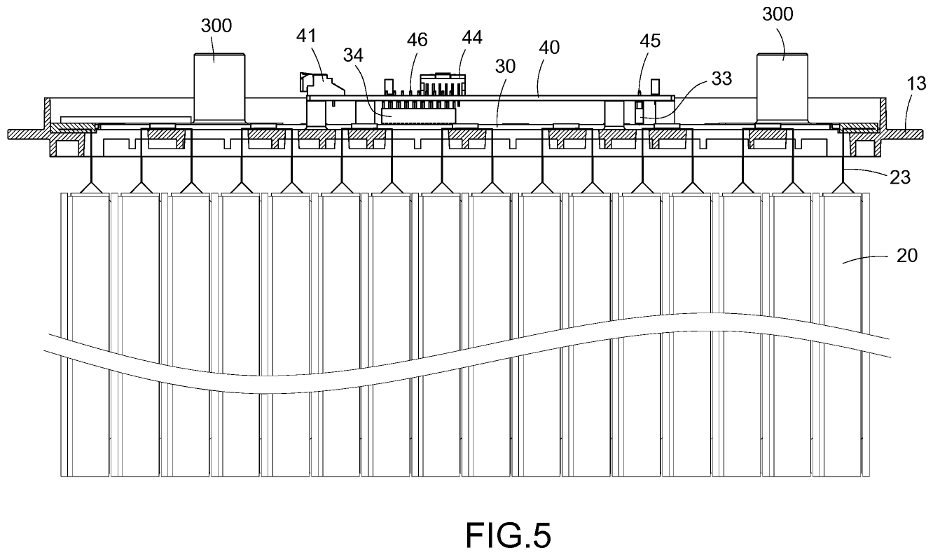

FIG. 2 and FIG. 3 are the disassembled schematic diagrams of a second embodiment of the battery module of the present disclosure. FIG. 4 is a structural diagram of the sensing unit of the battery module of the present disclosure. FIG. 5 is a cross-sectional view of the battery module of the present disclosure.

As shown in FIG. 2 to FIG. 4, the battery module 2 of the second embodiment of the present disclosure is similar to the battery module 1 of the first embodiment. The differences are that the body 10 includes a groove body 11, an upper cover 12, and a frame body 13, and the battery module 2 further include an output unit 40.

In some embodiments, a surface of the groove body 11 includes a plurality of protruding ribs 100 to strengthen a mechanical strength of the groove body 11, but there is not limited thereto.

In some embodiments, the battery units 20 are accommodated in the groove body 11. The sensing unit 30 and the output unit 40 are sandwiched between the battery units 20 and the upper cover 12. The frame body 13 is sandwiched between the groove body 11 and the upper cover 12. The frame body 13 is electrically connected to a ground terminal 31 of the sensing unit 30. The manufacturing materials of the groove body 11, the upper cover 12 and the frame body 13 may include rubber, plastic, steel, or aluminum, etc. The rubber may include vulcanized rubber (for example, the sulfur content is above 25% by weight), but there is not limited thereto. The plastic may include high-strength and high-density plastic such as acrylonitrile butadiene styrene (ABS), polypropylene (PP), styrene acrylonitrile resin (also known as AS polyester), polyvinyl chloride (PVC), urea formaldehyde (UF), melamine formaldehyde (MF), etc., but there is not limited thereto.

In some embodiments, the upper cover 12 includes a communication port 121 and a power output port 122. The communication port 121 is electrically connected to the sensing unit 30, and is used for outputting the voltage signal 21 and the temperature signal 22 of each battery unit 20, but there is not limited thereto. The power output port 122 is used to output an electric power of the plurality of battery units 20 (for example, electrode post 300 for connecting the plurality of battery units 20 in series or in parallel), but there is not limited thereto.

In some embodiments, the groove body 11, the upper cover 12 and the frame body 13 may be fixed by a plurality of locking holes 200 to enhance an overall stability and mechanical strength (for example, conductivity, insulation, weather resistance, shock resistance, etc.) of the battery module 2, but there is not limited thereto.

In some embodiments, the output unit 40 is arranged in the body 10, and is electrically and detachably connected to the sensing unit 30, and is configured to output the plurality of voltage signals 21 and the plurality of temperature signals 22 to outside of the battery module 2.

In some embodiments, the output unit 40 may be coupled to an external device (for example, a command unit, a cloud server, a mobile communication device, etc.) through a wired protocol, and the hardware connection may be accomplished by USB port, micro-USB port, RJ-45 port or serial port. The wired protocol may include at least one of a controller area network (also known as CAN or CAN bus), an on-board diagnostics (OBD) system, and a local interconnect network (also known as LIN or LIN bus). A physical line of the on-board diagnostic system may be called a K-line, but there is not limited thereto.

In some embodiments, the output unit 40 may be coupled to an external device (for example, a command unit, a cloud server, a mobile communication device, etc.) through a wireless protocol, and the hardware connection may be accomplished by a wireless transceiver antenna and a receiving chip. The wireless protocol may include Bluetooth, radio frequency (RF), near field communication (NFC), infrared (IR), Wi-Fi, LoRa, or Zigbee, etc., but there is not limited thereto.

In some embodiments, the mobile communication device may be any electronic device capable of connecting to an external network, such as a smart phone, a personal digital assistant (PDA), a tablet computer, a notebook computer (NB), etc., but there is not limited thereto.

In some embodiments, the output unit 40 includes a first transmission port 41, a second transmission port 42, a control unit 43, and a power port 44. The first transmission port 41 is configured to output the voltage signals 21 to outside of the battery module 2, the second transmission port 42 is configured to output the temperature signals 22 to outside of the battery module 2, but there is not limited thereto. The control unit 43 is used to execute the wired protocol or the wireless protocol. The power port 44 is used to receive power from the plurality of battery units 20, and transmit the power to the control unit 43 for a normal operation, but there is not limited thereto.

In some embodiments, the first transmission port 41 and the second transmission port 42 are electrically connected to outside of the battery module 2 selectively through the communication port 121 of the upper cover 12, and may be compatible with USB port, micro-USB port, RJ-45 port or serial port, etc., but there is not limited thereto.

In some embodiments, the control unit 43 may include one of a microcontroller (MCU), a microprocessor (MPU), a central processing unit (CPU), an application specific integrated circuit (ASIC), or a system-on-chip (SoC). The control unit 43 may also be a single-chip computer based on the Linux operating system architecture, and the single-chip computer may be a raspberry Pi, and its model includes 1A, 1A+, 1B, 1B+, 2B type, 3B type, 3B+ type, 3A+ type or 4B type, etc., but there is not limited thereto.

Please refer to FIG. 2 to FIG. 5. In some embodiments, the sensing unit 30 further includes a plurality of solder pads 32 arranged in pairs, and a first-row socket 33 and a second-row socket 34 arranged perpendicular to each other. It should be noted that the first-row socket 33 and the second-row socket 34 include a plurality of sockets respectively. The output unit 40 further includes a first-row pin 45 and a second-row pin 46 arranged perpendicular to each other. It should be noted that the first-row pin 45 and the second-row pin 46 include a plurality of pins respectively.

In some embodiments, the plurality of solder pads 32 are soldered with the plurality of electrodes 23 (for example, tabs) of the battery units 20. In some embodiments, the sensing unit is a printed circuit board (PCB) made of an FR-4 substrate. The FR-4 substrate includes at least one of glass fiber, epoxy resin, and BT resin. The BT resin is mainly composed of bismaleimide (BMI) and triazine, and is added with epoxy resins, polyphenylene ether (PPE), or allyl compounds etc. as a thermosetting resin formed as a modified component. The materials for the PCB may be flexible copper clad laminate (FCCL) and resin coated copper (RCC). The RCC is another material type of multilayer board, which is for the production of laminates. The quality of the resin determines a reliability of the PCB. PCB substrates of related arts are mostly composed of three components such as copper foil, reinforcement, and epoxy. The fillers may also be added to the PCB to improve heat resistance or flame resistance of the PCB. There is not limited thereto.

In some embodiments, one of the production modes for soldering the plurality of solder pads 32 and the plurality of electrodes 23 is to perform a front-end operation of a surface mount technology (SMT) process in advance. Using a machine to automatically brush metal (for example, tin) on the entire PCB to make a distribution of solder paste amount be more stable. When PCB is produced through SMT, volatiles (such as rosin or flux, etc.) may be splashed during the tin melting process, and that may result in many abnormal conditions (such as an oxidation on a surface of the substrate caused by the soldering flux, etc.). As a result, the subsequent process, such as die bonding and wire bonding, is likely to encounter the problems, for example, a metal bonding wire is not able to be soldered to the PCB, and that may cause technical problems such as low shear of solder ball, false soldering, or sliding ball, etc.

Therefore, another production mode for soldering the plurality of solder pads 32 and the plurality of electrodes 23 is to put the plurality of electrodes 23 at the end of a production station for SMT operation. In this way, it is expected to avoid the technical problems derived from the above-mentioned problem of splashing volatiles during the tin melting process, but there is not limited thereto.

In some embodiments, the first-row socket 33 is electrically connected to the plurality of solder pads 32, and configured to transmit a plurality of voltage signals 21. The first-row pin is conductively inserted in the first-row socket 33, and configured to receive the plurality of voltage signals 21, but there is not limited thereto. The second-row socket 34 is configured to transmit a plurality of temperature signals 22. The second-row pin 46 is conductively inserted in the second-row socket 34, and configured to receive the plurality of temperature signals 22, but there is not limited thereto.

In some embodiments, the output unit 40 and the sensing unit 30 are electrically and detachably connected, when the output unit 40 is abnormal, the user may easily replace that, which has a benefits of cost saving and convenient maintenance.

As shown in FIG. 4, in some embodiments, the sensing unit 30 further includes a plurality of temperature sensors 35 and a plurality of current limiting elements 36. Each temperature sensor 35 is arranged to straddle an electrical path 301 between one of the pluralities of solder pads 32 and the first-row socket 33, and configured to sense the temperature signal 22 of each battery unit 20. Each current limiting element 36 is electrically connected to one of the pluralities of solder pads 32 and the first-row socket 33 respectively.

In some embodiments, the temperature sensor 35 may include a thermocouple (TC), a diode (for example, LED), a thermally sensitive resistance, a resistance temperature detector (RTD), an IC temperature sensor, an acoustic temperature sensor, an infrared sensor, and a microwave sensor, etc., but there is not limited thereto.

In some embodiments, the current limiting element 36 is configured to limit a magnitude of a current input by the plurality of solder pads 32 to prevent the first-row socket 33 or the output unit 40 from being burned out by high current. In some embodiments, a fuse or a resistor may be used to implement a current limiting function, but there is not limited thereto.

In some embodiments, the sensing unit 30 may further include a C-shaped notch 37, a through hole 38, and the plurality of locking holes 200. The C-shaped notch 37 and the through hole 38 are used for the electrode post 300 to pass through. The sensing unit 30 may be locked to the frame body 13 through the plurality of locking holes 200 to enhance the overall stability and mechanical strength (for example, conductivity, insulation, weather resistance, shock resistance, etc.) of the battery module 2, but there is not limited thereto.

In some embodiments not shown in figures, the battery module 2 may further include a speaker. The speaker may include dynamic speaker, electromagnetic speaker, piezoelectric speaker, electrode speaker or plasma arc speaker, etc. A sound is generated when the battery unit 20, the sensing unit 30 or the output unit 40 is abnormal, but there is not limited thereto.

Therefore, the battery module 2 of the present disclosure transmits the voltage signal 21 and the temperature signal 22 of each battery unit 20 obtained by the sensing unit 30 to outside of the battery module 2 through the output unit 40 by wired or wireless transmission. In the embodiment shown in the figures, the sensing unit 30 is electrically connected to the communication port 121 of the upper cover 12 through the first transmission port 41 and the second transmission port 42. The voltage signal 21 and the temperature signal 22 of each battery unit 20 are transmitted to outside of the battery module 2 in a wired manner. That may avoid a situation in related art that the wires are directly drawn from each battery unit 20 to outside of the battery module 2. Since the output unit 40 and the sensing unit 30 are electrically and detachably connected, when the output unit 40 is abnormal, the user may easily replace that, which has the benefits of cost saving and convenient maintenance.

In summary, the battery module of the present disclosure adopts the architecture of arranging the sensing unit in the body. The external box for monitoring voltage and temperature in the related art, which occupies extra space, is eliminated. The battery module of the present disclosure does not need redundant transmission lines connected between the battery module and the external box. While monitoring the voltage and temperature of each battery unit, a user does not have to worry about accidentally losing the sensing unit during transporting or arranging the battery module, and the problems such as large resistance value, etc, caused by breaking or bending of the transmission lines, may be avoided.

In some embodiments, the battery module of the present disclosure transmits the voltage signal and the temperature signal of each battery unit obtained by the sensing unit to outside of the battery module through the output unit by wired or wireless transmission. In the embodiment shown in the figures, the sensing unit is electrically connected to the communication port of the upper cover through the first transmission port and the second transmission port. The voltage signal and the temperature signal of each battery unit are transmitted to outside of the battery module in a wired manner. That may avoid a situation in related art that the wires are directly drawn from each battery unit to outside of the battery module. Since the output unit and the sensing unit are electrically and detachably connected, when the output unit is abnormal, the user may easily replace that, which has the benefits of cost saving and convenient maintenance, but there is not limited thereto.

For those reasons, the battery module in the present disclosure is ensured for the sensing function of voltage and temperature being normally operated, so as to achieve a purpose of improving safety in use of the battery module.

The above is only a detailed description and drawings of the preferred embodiments of the present disclosure, but the features of the present disclosure are not limited thereto, and are not intended to limit the present disclosure. All the scope of the present disclosure shall be subject to the scope of the following claims. The embodiments of the spirit of the present disclosure and its similar variations are intended to be included in the scope of the present disclosure. Any variation or modification that may be easily conceived by those skilled in the art in the field of the present disclosure may be covered by the following claims.

What is claimed is:

1. A battery module comprising:
a body;
a plurality of battery units, arranged in the body; and
a sensing unit, arranged in the body and electrically connected with the battery units, and comprising a plurality of solder pads arranged in pairs, a first-row socket, a second-row socket, and a plurality of temperature sensors;
wherein the sensing unit is fixed on the battery units and configured to sense a voltage signal and a temperature signal of each battery unit;
wherein the solder pads are soldered with a plurality of electrodes of the battery units, the first-row socket is electrically connected to the solder pads and configured to transmit a plurality of voltage signals, the second-row socket is configured to transmit a plurality of temperature signals, each temperature sensor is arranged to straddle an electrical path between one of the solder pads and the first-row socket to sense the temperature signal of each battery unit.

2. The battery module of claim 1, further comprising: an output unit, arranged in the body, and electrically and detachably connected to the sensing unit, and configured to output the voltage signals and the temperature signals to outside of the battery module.

3. The battery module of claim 2, wherein, the body comprises a groove body and an upper cover the battery units are accommodated in the groove body and the sensing unit and the output unit are sandwiched between the battery units and the upper cover.

4. The battery module of claim 3, wherein, the body further comprises a frame body sandwiched between the groove body and the upper cover, and the frame body is electrically connected to a ground terminal of the sensing unit.

5. The battery module of claim 1, wherein, the output unit comprises a first-row pin and a second-row pin arranged perpendicular to each other, the first-row pin is conductively inserted in the first-row socket and configured to receive the voltage signals, and the second-row pin is conductively inserted in the second-row socket and configured to receive the temperature signals.

6. The battery module of claim 1, wherein, the sensing unit further comprises a plurality of current limiting elements, each current limiting element is electrically connected with one of the solder pads and the first-row socket respectively.

7. The battery module of claim 1, wherein, the output unit comprises a first transmission port and a second transmission port, the first transmission port is configured to output the voltage signals to outside of the battery module, the second transmission port is configured to output the temperature signals to outside of the battery module.
